(19) United States
(12) Patent Application Publication
(10) Pub. No.: US 2024/0053685 A1
(43) Pub. Date: Feb. 15, 2024

(54) PHOTOMASK PROCESSING APPARATUS AND METHOD OF PROCESSING PHOTOMASK

(71) Applicant: SEMES CO., LTD., Cheonan-si (KR)

(72) Inventors: Youngdae Chung, Incheon (KR); Jihoon Jeong, Hwaseong-si (KR); Kihoon Choi, Cheonan-si (KR); Taehee Kim, Yongin-si (KR); Sehoon Oh, Cheonan-si (KR)

(73) Assignee: SEMES CO., LTD., Cheonan-si (KR)

(21) Appl. No.: 18/231,727

(22) Filed: Aug. 8, 2023

(30) Foreign Application Priority Data
Aug. 11, 2022 (KR) 10-2022-0100588

(51) Int. Cl. G03F 7/00; G03F 7/20; G03F 7/09

(52) U.S. Cl. CPC G03F 7/70291; G03F 7/2043; G03F 7/091; G03F 7/70241; G03F 7/70875; G03F 7/70141

(57) ABSTRACT

Provided is a photomask processing apparatus including a light source, a photomask including a first surface provided with a plurality of patterns, an inspector configured to detect a target correction region including at least one target correction pattern, and a digital micromirror device (DMD) including a plurality of mirror blocks, and the DMD is further configured to switch, to the on state, mirror blocks corresponding to the target correction region of the first surface of the photomask among the plurality of mirror blocks, and switch, to the off state, mirror blocks corresponding to a non-correction region among the plurality of mirror blocks, the non-correction region being a region other than the target correction region on the first surface of the photomask.

### CROSS-REFERENCE TO RELATED APPLICATION

This application is based on and claims priority under 35 U.S.C. § 119 to Korean Patent Application No. 10-2022-0100588, filed on Aug. 11, 2022, in the Korean Intellectual Property Office, the disclosure of which is incorporated by reference herein in its entirety.

### BACKGROUND

### 1. Field

The disclosure relates to a photomask processing apparatus and a photomask processing method, and more particularly, to a photomask processing apparatus and a photomask processing method, by which a critical dimension of a photomask, particularly a photomask usable in an extreme ultraviolet (EUV) photolithography process, is corrected.

### 2. Description of the Related Art

To implement a semiconductor device on a semiconductor substrate, a photolithography technique including exposure and development processes is used. In accordance with the trend of downscaling of semiconductor devices, in forming a mask pattern on a semiconductor substrate, extreme ultraviolet (EUV) light is used as a light source of an exposure apparatus. In forming a plurality of fine patterns arranged at high density by using an EUV lithography process, research on a technique for transferring a pattern to a wafer by using a reflective exposure system including a reflective EUV photomask is being actively conducted. In the case of a reflective photomask, because a pattern on the photomask is transferred to a wafer through a scanning process, defects in the photomask cause defects in devices implemented on the wafer. In this regard, various errors may occur in the manufacturing process of a reflective photomask. Accordingly, a technique for improving the yield of EUV photomasks by effectively correcting various errors of the photomask is required.

### SUMMARY

Provided is a photomask processing apparatus by which a critical dimension of a photomask pattern may be corrected.

Provided is a photomask processing method by which a critical dimension of a photomask pattern may be corrected.

In addition, the issues to be solved by the technical idea of the disclosure are not limited to those mentioned above, and other issues may be clearly understood by those of ordinary skill in the art from the following descriptions.

Additional aspects will be set forth in part in the description which follows and, in part, will be apparent from the description, or may be learned by practice of the presented embodiments of the disclosure.

According to an aspect of the disclosure, a photomask processing apparatus includes a light source configured to emit light along an optical axis, a photomask including a first surface provided with a plurality of patterns, an inspector configured to detect a target correction region including at least one target correction pattern having a dimension greater than a predetermined target range, among the plurality of patterns, and a digital micromirror device (DMD) including a plurality of mirror blocks and configured to switch each of the plurality of mirror blocks between an on state and an off state, wherein each of the plurality of mirror blocks is configured to, in the on state, reflect the emitted light toward the first surface of the photomask and, in the off state, reflect the emitted light toward outside of the first surface of the photomask, and the DMD is further configured to switch, to the on state, mirror blocks corresponding to the target correction region of the first surface of the photomask among the plurality of mirror blocks, and switch, to the off state, mirror blocks corresponding to a non-correction region among the plurality of mirror blocks, the non-correction region being a region other than the target correction region on the first surface of the photomask.

In an embodiment, the at least one target correction pattern may include a pattern having a critical dimension greater than a deviation of a target critical dimension of each of the plurality of patterns, among the plurality of patterns.

In an embodiment, the photomask processing apparatus may further include a fluid supply unit configured to supply an etchant to the first surface of the photomask.

In an embodiment, on-off state switching of each of the plurality of mirror blocks may be performed through rotation of each of the plurality of mirror blocks.

In an embodiment, the photomask processing apparatus may further include a bumper unit configured to absorb the light reflected by the plurality of mirror blocks in the off state.

In an embodiment, the photomask processing apparatus may further include a flat-top optical system configured to convert the light emitted along the optical axis into flat-top light.

In an embodiment, the photomask processing apparatus may further include a temperature measuring device configured to measure a temperature of the at least one target correction pattern, and a DMD controller configured to control on-off state switching of the plurality of mirror blocks of the DMD.

In an embodiment, the DMD controller may be further configured to control, based on the temperature of the at least one target correction pattern measured by the temperature measuring device, on-off states of the plurality of mirror blocks corresponding to the at least one target correction pattern so that the temperature of the at least one target correction pattern reaches a target temperature.

In an embodiment, the photomask processing apparatus may further include a light irradiation optical system configured to provide the light emitted along the optical axis to the DMD.

In an embodiment, the light irradiation optical system may be further configured to provide the light emitted along the optical axis to the DMD in a direction different from the optical axis.

In an embodiment, the DMD may include the plurality of mirror blocks arranged in the form of an L×M matrix.

In an embodiment, the photomask processing apparatus may further include a refractive lens configured to adjust magnification of the light reflected from the DMD.

According to another aspect of the disclosure, a photomask processing method includes preparing a photomask including a first surface provided with a plurality of patterns, determining a target correction region including at least one target correction pattern having a dimension greater than a predetermined target range, with respect to the photomask, supplying an etchant to the first surface of the photomask, and correcting a dimension of the at least one target correction pattern by irradiating light to the target correction region of the photomask, wherein the correcting of the dimension of the at least one target correction pattern includes preparing a digital micromirror device (DMD) including a plurality of mirror blocks each configured to be switched between an on state and an off state, each of the plurality of mirror blocks being further configured to, in the on state, reflect the light toward the first surface of the photomask and, in the off state, reflect the light toward outside of the first surface of the photomask, switching, to the on state, mirror blocks corresponding to the target correction region among the plurality of mirror blocks and switching, to the off state, mirror blocks corresponding to a non-correction region among the plurality of mirror blocks, the non-correction region being a region other than the target correction region on the first surface of the photomask, and providing the light to the DMD and etching the at least one target correction pattern by using the light reflected from the DMD.

In an embodiment, the at least one target correction pattern may include a pattern having a critical dimension greater than a deviation of a target critical dimension of each of the plurality of patterns, among the plurality of patterns.

In an embodiment, the preparing of the DMD may include adjusting magnification of the reflected light to correspond to a size of the photomask.

In an embodiment, on-off state of each of the plurality of mirror blocks is performed through rotation of each of the plurality of mirror blocks.

In an embodiment, in the etching of the at least one target correction pattern, the light may be provided to the DMD through a light irradiation optical system configured to change a path of the light.

In an embodiment, the correcting of the dimension of the at least one target correction pattern may further include measuring a temperature of the at least one target correction pattern, and feedback-controlling, based on the measured temperature, on-off states of the plurality of mirror blocks corresponding to the at least one target correction pattern so that the temperature of the at least one target correction pattern reaches a target temperature.

In an embodiment, the etching of the at least one target correction pattern may include converting the light into flat-top light.

According to another aspect of the disclosure, a photomask processing method includes preparing a mask blank including a mask substrate, a reflective multi-layer film located on the mask substrate and configured to reflect extreme ultraviolet (EUV) light, and an absorbing layer located on the reflective multi-layer film, etching the absorbing layer to provide a photomask including a first surface provided with a plurality of patterns, detecting a target correction region including at least one target correction pattern among the plurality of patterns, the at least one target correction pattern being a pattern having a greater width than a deviation of a critical dimension of each of the plurality of patterns, supplying an etchant to the first surface of the photomask, and correcting, in a state in which the etchant is supplied, a critical dimension of the at least one target correction pattern by irradiating light to the target correction region, wherein the correcting of the critical dimension of the at least one target correction pattern includes preparing a digital micromirror device (DMD) including a plurality of mirror blocks each configured to be switched between an on state and an off state, each of the plurality of mirror blocks being further configured to, in the on state, reflect the light toward the first surface of the photomask and, in the off state, reflect the light toward outside of the first surface of the photomask, switching, to the on state, mirror blocks corresponding to the target correction region among the plurality of mirror blocks and switching, to the off state, mirror blocks corresponding to a non-correction region among the plurality of mirror blocks, the non-correction region being a region other than the target correction region on the first surface of the photomask, and providing the light to the DMD and etching the at least one target correction pattern by using the light reflected from the DMD.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a block diagram for explaining a photomask processing method according to an embodiment;

FIG. 2 is a cross-sectional view of a mask blank for explaining a photomask according to an embodiment;

FIG. 3A is a cross-sectional view of a photomask for explaining a target critical dimension of a photomask pattern according to an embodiment, and FIG. 3B is a cross-sectional view of a photomask for explaining a critical dimension of a photomask pattern and a target correction region according to an embodiment;

FIG. 4 is a plan view of the photomask of FIG. 3B, viewed from an X-Y plane;

FIG. 5 is a schematic configuration diagram of a photomask processing apparatus according to an embodiment;

FIG. 6 is a schematic cross-sectional view of a fluid supply unit and a support unit according to an embodiment;

FIG. 7 is a block diagram for explaining a fourth operation according to an embodiment;

FIG. 8A is a schematic plan view of a digital micromirror device (DMD) according to an embodiment, and FIG. 8B is a plan view for explaining the DMD of FIG. 8A;

FIGS. 9A and 9B are schematic diagrams of an example of on-off state switching of a mirror block and a bumper unit according to an embodiment;

FIGS. 10A and 10B are graphs for explaining a flat-top optical system according to an embodiment; and

FIG. 11 is a schematic configuration diagram of a photomask processing apparatus according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

Hereinafter, embodiments of the disclosure will be described in detail with reference to the accompanying drawings. Like reference numerals in the drawings refer to like elements throughout, and redundant descriptions thereof are omitted.

In the following drawings, an X-axis direction and a Y-axis direction may represent directions parallel to an upper surface of a photomask, and the X-axis direction and the Y-axis direction may be directions perpendicular to each other. A Z-axis direction may represent a direction perpendicular to the upper surface of the photomask, and the Z-axis direction may be a direction perpendicular to an X-Y plane.

A photomask described in the following drawings may be an extreme ultraviolet (EUV) photomask, but is not limited thereto.

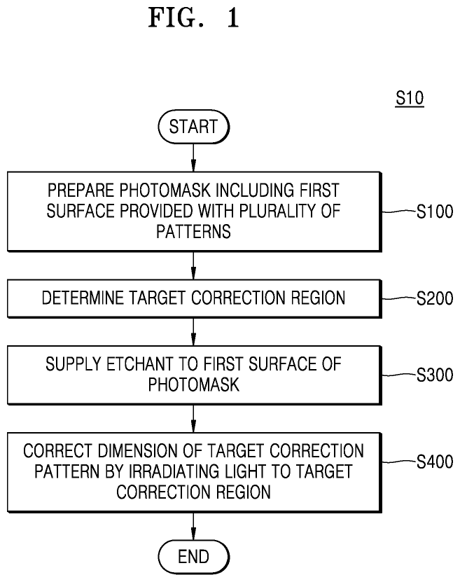

FIG. 1 is a block diagram for explaining a photomask processing method S10 according to an embodiment. Referring to FIG. 1, the photomask processing method S10 may include a process sequence of first to fourth operations S100, S200, S300, and S400.

When an embodiment is otherwise implementable, a specific process sequence may be performed differently from the sequence to be described. For example, two processes to be described in succession may be performed substantially simultaneously, or may be performed in an order reverse to the order to be described.

The photomask processing method S10 according to the disclosure may include the first operation S100 of preparing a photomask including a first surface provided with a plurality of patterns, the second operation S200 of determining a target correction region including at least one target correction pattern having a dimension greater than a predetermined target range, with respect to the photomask, the third operation S300 of supplying an etchant to the first surface of the photomask, and the fourth operation S400 of correcting the dimension of the at least one target correction pattern by irradiating light to the target correction region of the photomask.

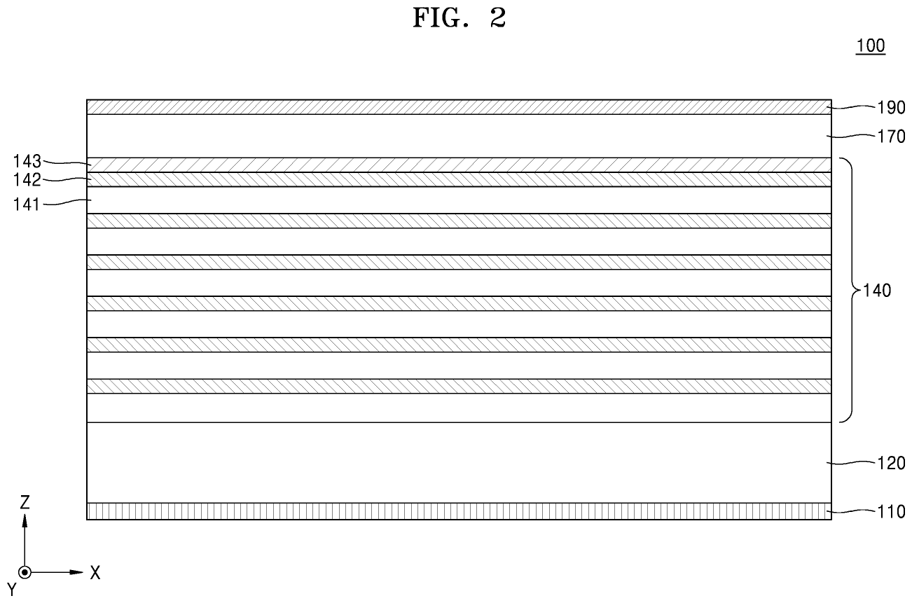

In the photomask processing method S10, the first operation S100 may be performed, for example, by etching a mask blank 100. The first operation S100 is described below in detail with reference to FIGS. 2 to 4.

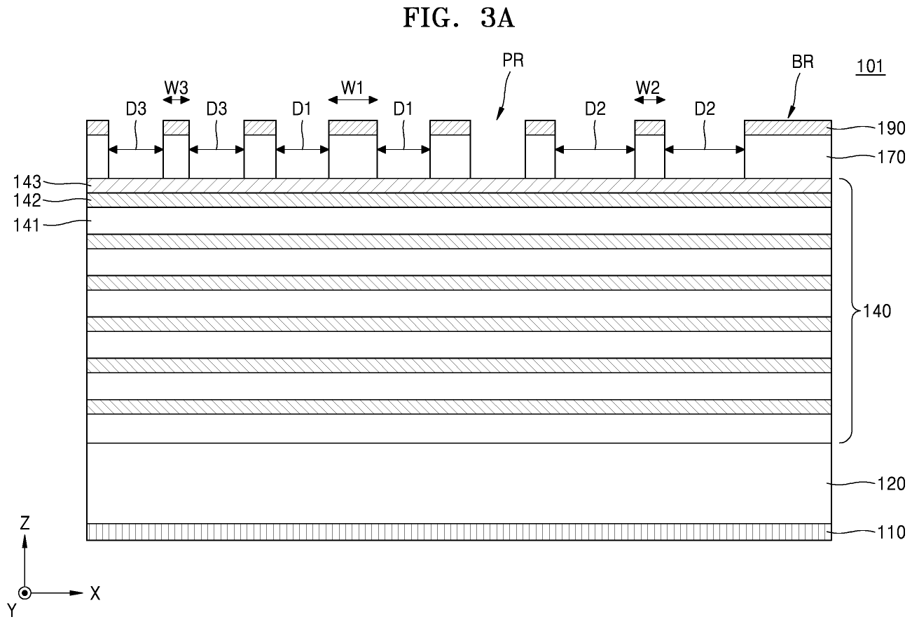

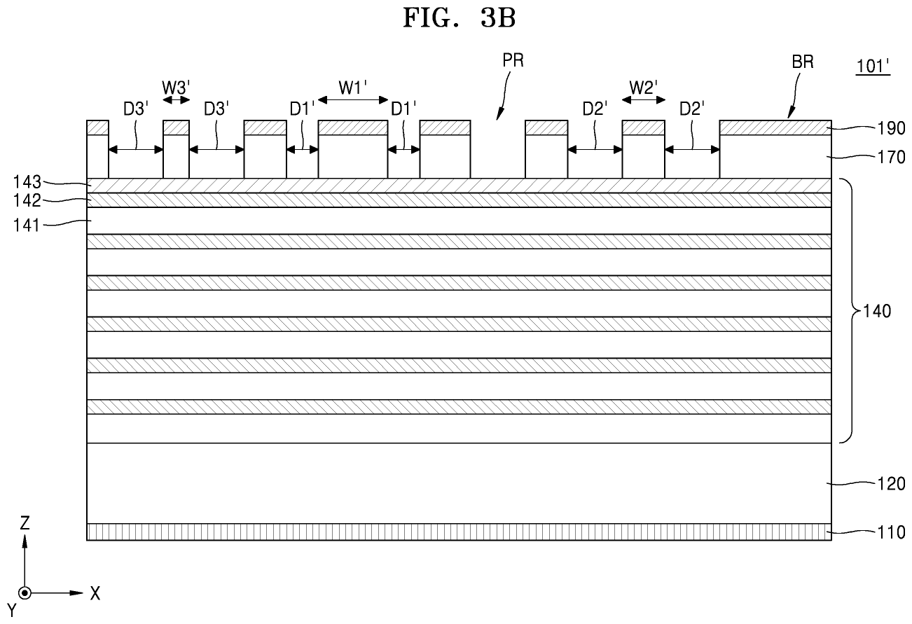

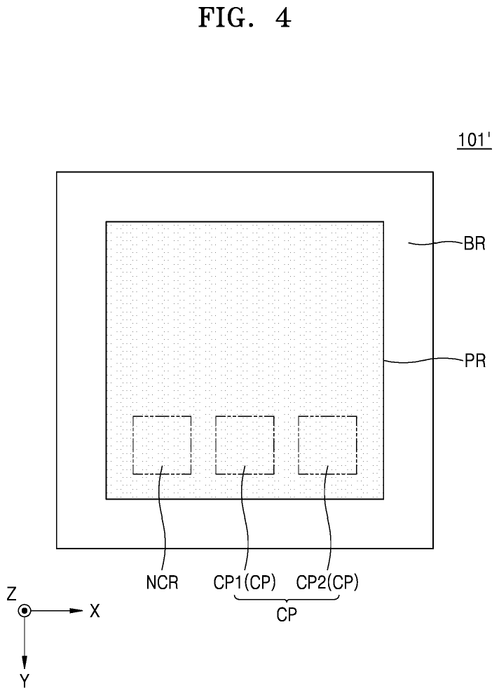

FIG. 2 is a cross-sectional view of the mask blank 100 for explaining a photomask according to an embodiment. FIG. 3A is a cross-sectional view of a photomask 101 for explaining a target critical dimension of a photomask pattern according to an embodiment, and FIG. 3B is a cross-sectional view of a photomask 101′ for explaining a critical dimension of a photomask pattern and a target correction region according to an embodiment. FIG. 4 is a plan view of the photomask of 101′ FIG. 3B, viewed from the X-Y plane.

Referring to FIGS. 1 to 4, the mask blank 100 may include a conductive layer 110, a mask substrate 120, a reflective multi-layer film 140 on the mask substrate 120, an absorbing layer 170 on the reflective multi-layer film 140, and an anti-reflective layer 190 on the absorbing layer 170. The mask blank 100 according to the present embodiment may be a mask blank for a reflective photomask.

The conductive layer 110 may be used to fix the photomask 101 (see FIG. 3A) to an electrostatic chuck of an exposure apparatus during an exposure process. The conductive layer 110 may include a chromium (Cr)-containing material or a tantalum (Ta)-containing material. For example, the conductive layer 110 may include Cr or CrN. The conductive layer 110 may have a thickness of about 20 nm to about 80 nm.

The mask substrate 120 may include a material having a low thermal expansion coefficient, such as silicon (Si). For example, the mask substrate 120 may have a thermal expansion coefficient of about 0±1.0×10⁻⁷/° C. at 20° C., but is not limited thereto. In addition, the mask substrate 120 may include a material having excellent smoothness, flatness, and resistance to a cleaning solution. For example, the mask substrate 120 may include synthetic quartz glass, quartz glass, aluminosilicate glass, soda-lime glass, low thermal expansion material (LTEM) glass, such as SiO₂—TiO₂-based glass, crystallized glass obtained by precipitating a 8-quartz solid solution, single-crystal silicon, or SiC.

The reflective multi-layer film 140 may include a material that reflects EUV light. According to embodiments, the reflective multi-layer film 140 may include a molybdenum (Mo)/Si periodic multi-layer film. The reflective multi-layer film 140 may include a first reflective layer 141, a second reflective layer 142, and a capping layer 143.

The reflective multi-layer film 140 may have a structure in which the first reflective layer 141 and the second reflective layer 142 are alternately stacked. According to embodiments, the first reflective layer 141 may include Mo or Si, and the second reflective layer 142 may include Si or Mo. According to embodiments, the first reflective layer 141 and the second reflective layer 142 may be stacked in several tens of layers, and may have various thicknesses. The capping layer 143 may be arranged on an uppermost layer of the reflective multi-layer film 140. The capping layer 143 may be configured to protect the reflective multi-layer film 140 from mechanical damage and/or chemical damage. According to embodiments, the capping layer 143 may include ruthenium (Ru) or a Ru compound.

The absorbing layer 170 may include a material that absorbs EUV light. When a surface of the absorbing layer 170 is irradiated with light in the wavelength range of EUV light, the absorbing layer 170 may include a material having a maximum light reflectance of about 5% or less around a wavelength of about 13.5 nm. The absorbing layer 170 may include, for example, TaN, TaNO, TaBO, TaBN, Lr, or the like. According to embodiments, a sputtering process may be used to form the absorbing layer 170, but the absorbing layer 170 is not limited thereto. In some embodiments, the absorbing layer 170 may have a thickness of about 30 nm to about 200 nm.

The anti-reflective layer 190 may be configured to obtain sufficient contrast by providing a relatively low reflectance in a wavelength band of inspection light, for example, a wavelength band of about 190 nm to about 260 nm, during inspection of pattern elements to be manufactured in a subsequent process. According to embodiments, the anti-reflective layer 190 may include a metal nitride, for example, a transition metal nitride, such as titanium nitride or tantalum nitride, and may further include at least one component selected from among chlorine, fluorine, argon, hydrogen, and oxygen. According to embodiments, the anti-reflective layer 190 may be formed by a sputtering process, but is not limited thereto. According to embodiments, the anti-reflective layer 190 may have a thickness of about 5 nm to about 25 nm. In some embodiments, the anti-reflective layer 190 may be formed by treating the surface of the absorbing layer 170 in an atmosphere containing the additional component or a precursor thereof.

In the photomask 101, a plurality of patterns PR may be formed by etching the absorbing layer 170 of the mask blank 100. In some embodiments, in the photomask 101, the plurality of patterns PR may be formed by etching the anti-reflective layer 190 together with the absorbing layer 170. The photomask 101 may further include a non-patterned region BR in which the absorbing layer 170 is not etched. In the photomask 101, a first surface on which the patterns PR are provided may be an upper surface of the photomask 101.

According to embodiments, each of the plurality of patterns PR of the photomask 101 may have a critical dimension. The critical dimension may be expressed as a line width of a pattern and a spacing between adjacent patterns. Each of the plurality of patterns PR of the photomask 101 may have a target critical dimension. The target critical dimension may be expressed as a line width of a pattern required during a process and a spacing between adjacent patterns. The plurality of patterns PR may have different target critical dimensions. According to embodiments, the plurality of patterns PR may have target critical dimensions corresponding to first to third widths W1, W2, and W3, respectively.

According to embodiments, the photomask 101′, in which the plurality of patterns PR are formed by etching the absorbing layer 170 of the mask blank 100, may include the plurality of patterns PR having a critical dimension different from the target critical dimension. According to embodiments, the plurality of patterns PR may have critical dimensions corresponding to first to third widths W1′ to W3′, respectively.

According to embodiments, some patterns of the plurality of patterns PR may have the first width W1′ as the critical dimension, and may have the first width W1 as the target critical dimension. The first width W1′, which is the critical dimension of the patterns, may have a greater width than the first width W1, which is the target critical dimension of the patterns. Likewise, a first distance D1′, which is a pattern distance of the patterns, may be less than a first distance D1, which is a pattern distance of the patterns when the patterns have the target critical dimension. In this case, a difference between the first width W1′, which is the critical dimension of the patterns, and the first width W1, which is the target critical dimension of the patterns, may be out of an allowable range according to a deviation of the critical dimension.

According to embodiments, some other patterns of the plurality of patterns PR may have a second width W2′ as the critical dimension, and may have a second width W2 as the target critical dimension. The second width W2′, which is the critical dimension of the patterns, may have a greater width than the second width W2, which is the target critical dimension of the patterns. Likewise, a second distance D2′, which is a pattern distance of the patterns, may be less than a second distance D2, which is a pattern distance of the patterns when the patterns have the target critical dimension. In this case, a difference between the second width W2′, which is the critical dimension of the patterns, and the second width W2, which is the target critical dimension of the patterns, may be out of an allowable range according to a deviation of the critical dimension.

According to embodiments, yet some other patterns of the plurality of patterns PR may have a third width W3′ as the critical dimension, and may have a third width W3 as the target critical dimension. The third width W3′, which is the critical dimension of the patterns, may be the same as the third width W3′, which is the target critical dimension of the patterns, or a difference between the third width W3′ and the third width W3 may be within an allowable range according to a deviation. Accordingly, a third distance D3′, which is a pattern distance of the patterns, may be the same as a third distance D3, which is a pattern distance of the patterns when the patterns have the target critical dimension, or a difference between the third distance D3′ and the third distance D3 may be within an allowable range according to a deviation.

A target correction pattern CP may be a pattern that requires dimension correction, among the plurality of patterns PR. A plurality of target correction patterns CP may be provided. A target correction region CR may be a region that requires correction on a first surface of the photomask 101′. The target correction region CR may include at least one target correction pattern CP.

According to embodiments, the target correction pattern CP may be a pattern in which a critical dimension of the pattern has a greater width than a target critical dimension thereof, and a difference between the critical dimension and the target critical dimension is out of an allowable range. The target correction region CR may be a region that requires critical dimension correction on the first surface of the photomask 101′.

For example, in the case of a pattern having the first width W1′ as the critical dimension, among the plurality of patterns PR, the first width W1′ may have a greater width than the first width W1, which is the target critical dimension of the pattern, and a difference between the first width W1′ and the first width W1 may exceed a deviation within an allowable range. Accordingly, the pattern may require critical dimension correction. In this case, the pattern that has the first width W1′ as the critical dimension and requires correction may be a first target correction pattern CP1.

In addition, in the case of a pattern having the second width W2′ as the critical dimension, among the plurality of patterns PR, the second width W2′ may have a greater width than the second width W2, which is the target critical dimension of the pattern, and a difference between the second width W2′ and the second width W2 may exceed a deviation within an allowable range. Accordingly, the pattern may require critical dimension correction. In this case, the pattern that has the second width W2′ as the critical dimension and requires correction may be a second target correction pattern CP2.

In this case, the target correction region CR may include the first target correction pattern CP1 and the second target correction pattern CP2. That is, the target correction region CR may be a region corresponding to the first target correction pattern CP1 and the second target correction pattern CP2 on the first surface of the photomask 101′.

As used herein, the singular forms of the pattern RP and the target correction pattern CP may include the plural forms thereof unless the context clearly indicates otherwise.

In FIGS. 3A, 3B, and 4, two target correction patterns CP, that is, the first and second target correction patterns CP1 and CP2, are shown. However, the number of target correction patterns is not limited thereto, and one or three or more target correction patterns CP may be provided.

In addition, in FIGS. 3A, 3B, and 4, the target correction pattern CP is shown as a pattern among the plurality of patterns PR in which the critical dimension of each of the plurality of patterns PR has a greater width than the target critical dimension thereof, and the difference between the critical dimension and the target critical dimension is a deviation out of the allowable range, but the target correction pattern CP is not limited thereto. The target correction pattern CP may be a pattern that deviates from a target dimension in terms of flatness error of a photomask, thickness variation of a photomask, critical dimension uniformity (CDU), and the like.

A non-correction region NCR may be a region that does not correspond to the target correction region CR on the first surface of the photomask 101′. According to embodiments, the non-correction region NCR may be a region that does not require dimension correction, among the plurality of patterns PR of the photomask 101′. According to embodiments, the non-correction region NCR may be a region that does not require critical dimension correction, among the plurality of patterns PR of the photomask 101′.

In addition, in the case of a pattern having the second width W2′ as the critical dimension, among the plurality of patterns PR, the second width W2′ may have a greater width than the second width W2, which is the target critical dimension of the pattern, and a difference between the second width W2′ and the second width W2 may exceed a deviation within an allowable range. Accordingly, the pattern may require critical dimension correction. In this case, the pattern that has the second width W2′ as the critical dimension and requires correction may be a second target correction pattern CP2.

For example, in the case of a pattern having the third width W3′ as the critical dimension, among the plurality of patterns PR, the third width W3′ may be the same as the third width W3, which is the target critical dimension of the pattern, or a difference between the third width W3′ and the third width W3 may be within an allowable range according to deviation. Accordingly, the pattern may not require critical dimension correction. In this case, the pattern that has the third width W3′ as the critical dimension and does not require correction may be included in the non-correction region NCR.

The second operation S200 of detecting the target correction region, the third operation S300 of supplying the etchant to the first surface of the photomask, and the fourth operation S400 of correcting the dimension of the at least one target correction pattern by irradiating light to the target correction region of the photomask may be performed by a photomask processing apparatus 1000.

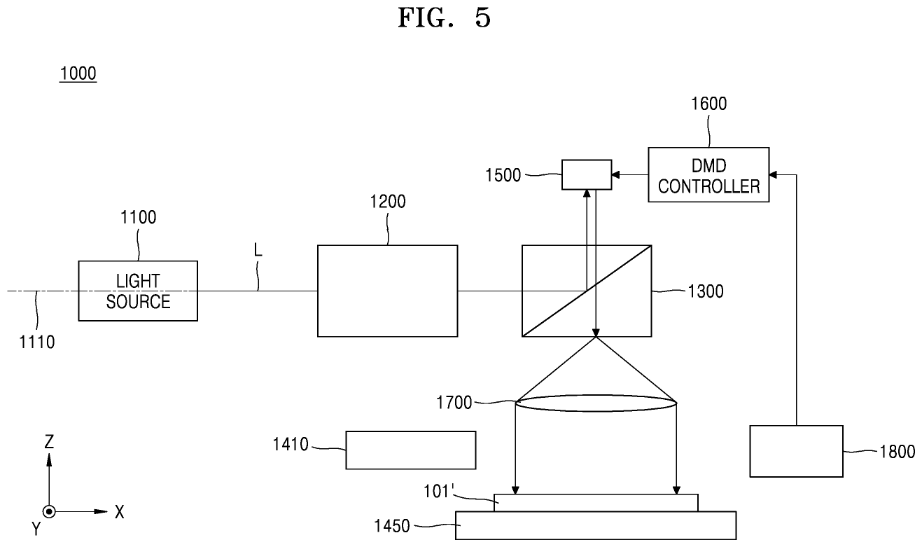

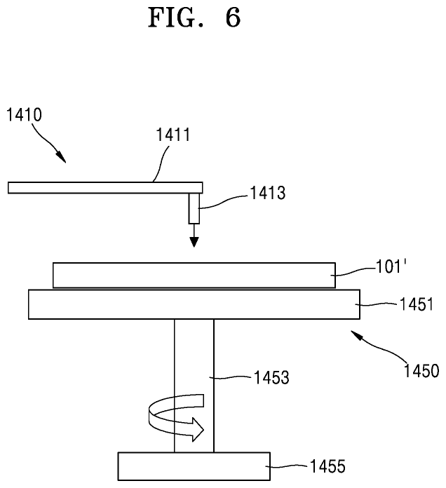

FIG. 5 is a schematic configuration diagram of the photomask processing apparatus 1000 according to an embodiment. FIG. 6 is a schematic cross-sectional view of a fluid supply unit 1410 and a support unit 1450 according to an embodiment.

Referring to FIGS. 5 and 6, the photomask processing apparatus 1000 may include an inspector 1800, the support unit 1450, the fluid supply unit 1410, a light source 1100, a digital micromirror device (DMD) 1500, and a DMD controller 1600.

The inspector 1800 may be configured to detect the target correction pattern CP that requires correction, among the plurality of patterns PR on the first surface of the photomask 101′. According to embodiments, the inspector 1800 may detect the target correction pattern CR that requires critical dimension correction, among the plurality of patterns PR. According to embodiments, to detect the target correction pattern CR of the photomask 101′, the inspector 1800 may measure various characteristics measurable on a front side or a back side of the photomask 101′. According to embodiments, the inspector 1800 may detect regions having errors, such as flatness error, thickness variation of a photomask, and critical dimension uniformity (CDU).

At least one target correction pattern CP may be detected by the inspector 1800 of the photomask processing apparatus 1000, and accordingly, the second operation S200 of determining the target correction region may be performed.

The support unit 1450 may be configured to support a lower surface of the photomask 101′, that is, a surface opposite to the first surface of the photomask 101′. The support unit 1450 may include a support 1451, a support bar 1453, and an actuator 1455. The support 1451 may support the lower surface of the photomask 101′ during a process. The support bar 1453 may support a central portion of the lower surface of the support 1451, and may be configured to be rotatable in a direction indicated by an arrow in FIG. 6. The actuator 1455 may be configured to adjust a height of the support 1451. According to embodiments, the actuator 1455 may be configured to move in a vertical direction.

The fluid supply unit 1410 may be configured to supply an etchant to the photomask 101′. In some embodiments, the etchant may include at least one of ammonia water (NH₄OH) and tetramethylammonium hydroxide (TMAH). In some embodiments, the etchant may include a mixture of ammonium hydroxide (NH₃OH), hydrogen peroxide (H₂O₂), and ultrapure water (H₂O), a mixture of ammonia (NH₃) and deionized water, ultrapure water with carbon dioxide added thereto, and the like. The fluid supply unit 1410 may include a fluid supply line 1411 and a nozzle 1413. According to embodiments, the etchant may be supplied to the nozzle 1413 through the fluid supply line 1411, and may be supplied from the nozzle 1413 to the first surface of the photomask 101′. In this case, the photomask 101′ may be supported by the support 1451, the support 1451 may be rotated due to rotation of the support bar 1453, and accordingly, the etchant discharged from the nozzle 1413 may be supplied to the plurality of patterns PR on the first surface of the photomask 101′.

Accordingly, the third operation S300 of supplying the etchant to the first surface of the photomask may be performed by the fluid supply unit 1410 and the support unit 1450.

The light source 1100 may be configured to emit light L along an optical axis 1110.

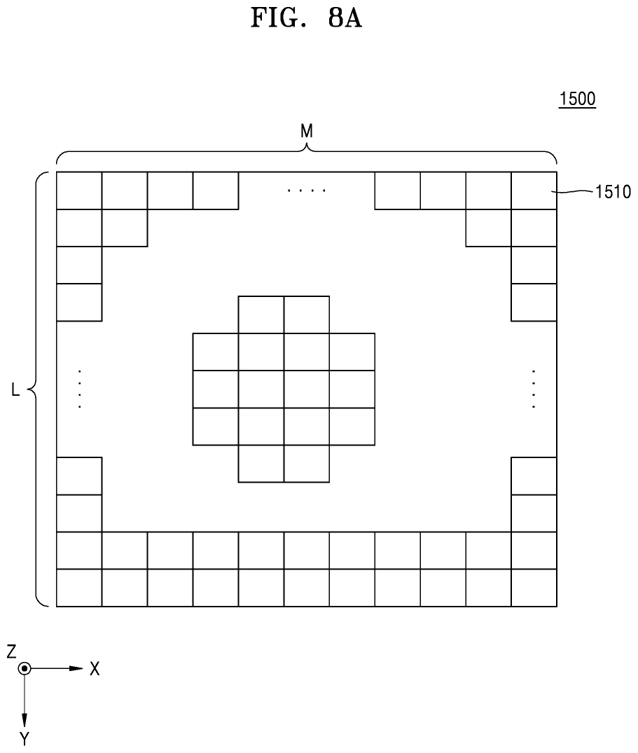

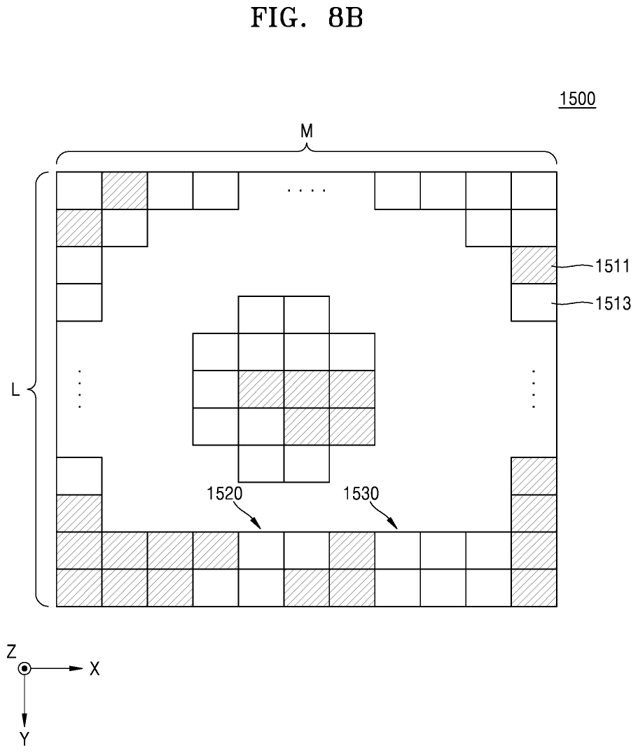

The DMD 1500 may be configured to reflect the light L emitted along the optical axis 1110 to the photomask 101′. According to embodiments, the DMD 1500 may reflect the light L on the first surface of the photomask 101′. According to embodiments, the DMD 1500 may reflect the light L emitted along the optical axis 1110 to the plurality of patterns PR of the photomask 101′. The DMD 1500 may include a plurality of mirror blocks 1510 (see FIG. 8A) configured to be switched between an on state 1513 and an off state 1511. An on-off state of the DMD 1500 and a detailed description thereof are described below with reference to FIGS. 8A and 8B.

The DMD controller 1600 may be configured to control an on-off state of each of the mirror blocks 1510 (see FIG. 8A) of the DMD 1500. The DMD controller 1600 may be implemented in hardware, firmware, software, or any combination thereof. For example, the DMD controller 1600 may include a computing device, such as a workstation computer, a desktop computer, a laptop computer, or a tablet computer. The DMD controller 1600 may include a simple controller, a complex processor, such as a microprocessor, a central processing unit (CPU), or a graphics processing unit (GPU), a processor configured by software, dedicated hardware, or firmware. The DMD controller 1600 may be implemented by, for example, a general-purpose computer or application-specific hardware, such as a digital signal processor (DSP), a field-programmable gate array (FPGA), and an application-specific integrated circuit (ASIC). The DMD controller 1600 may be implemented as instructions stored on a machine-readable medium that may be read and executed by one or more processors. Here, the machine-readable medium may include any mechanism for storing and/or transmitting information in a form readable by a machine (e.g., a computing device). For example, the machine-readable medium may include read-only memory (ROM), random-access memory (RAM), magnetic disk storage media, optical storage media, flash memory devices, electrical, optical, acoustical, or other form of propagated signals (e.g., carrier waves, infrared signals, digital signals, etc.), and any other signals.

A detailed description of the DMD controller 1600 is described below with reference to FIGS. 8A and 8B.

In some embodiments, the photomask processing apparatus 1000 may further include a light irradiation optical system 1300. The light irradiation optical system 1300 may be configured to provide the light L emitted along the optical axis 1110 to the DMD 1500. According to embodiments, the light irradiation optical system 1300 may be configured to provide the light L emitted along the optical axis 1110 to the DMD 1500 in a direction different from the optical axis 1110. According to embodiments, the light irradiation optical system 1300 may be configured such that the light L emitted along the optical axis 1110 is provided to the DMD 1500 in a direction perpendicular to the optical axis 1110.

According to embodiments, the photomask processing apparatus 1000 may further include a refractive lens 1700. The refractive lens 1700 may be configured to adjust magnification of the light L reflected from the DMD 1500. According to embodiments, the refractive lens 1700 may adjust the magnification of the light L reflected from the DMD 1500 to correspond to an area of the first surface of the photomask 101′. According to embodiments, the refractive lens 1700 may adjust the magnification of the light L reflected from the DMD 1500 to correspond to an area of the plurality of patterns PR of the photomask 101′. For example, because the area of the first surface of the photomask 101′ is relatively small, when the DMD 1500 reflects the light L to an area exceeding the area of the plurality of patterns PR of the photomask 101′, the magnification of the light L may be increased through the refractive lens 1700 so that the light L is concentrated on the patterns PR of the photomask 101′. In this case, a convex lens may be used as the refractive lens 1700. In addition, in some embodiments, because the area of the first surface of the photomask 101′ is relatively large, when the DMD 1500 reflects the light L on only some of the patterns PR of the photomask 101′, a concave lens may be used as the refractive lens 1700 so that the light L is reflected on all of the patterns PR of the photomask 101′.

Accordingly, light may be irradiated to the patterns PR through the DMD 1500 even for the photomasks 101′ having different sizes.

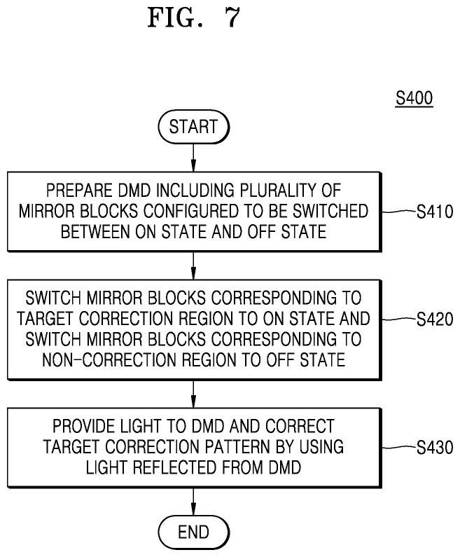

According to embodiments, the fourth operation S400 of correcting the dimension of the target correction pattern by irradiating light to the target correction region in the photomask processing method S10 may be performed through the light source 1100, the DMD 1500, and the DMD controller 1600. The fourth operation S400 is described below in detail with reference to FIGS. 7, 8A, and 8B.

FIG. 7 is a block diagram for explaining the fourth operation S400 according to an embodiment. FIG. 8A is a schematic plan view of the DMD 1500 according to an embodiment, and FIG. 8B is a plan view for explaining the DMD 1500 of FIG. 8A.

Referring to FIG. 7, the fourth operation S400 of correcting the dimension of the target correction pattern by irradiating light to the target correction region may include operation S410 of preparing a DMD including a plurality of mirror blocks configured to be switched between an on state and an off state, operation S420 of switching mirror blocks corresponding to the target correction region to the on state and switching mirror blocks corresponding to a non-correction region to the off state, and operation S430 of providing the light to the DMD and correcting the target correction pattern by using the light reflected from the DMD.

Operation S410 of preparing the DMD including the plurality of mirror blocks configured to be switched between the on state and the off state, and operation S420 of switching the mirror blocks corresponding to the target correction region to the on state and switching the mirror blocks corresponding to the non-correction region to the off state may be performed through, for example, the DMD 1500 and the DMD controller 1600.

Referring to FIGS. 5, 8A, and 8B, the DMD 1500 may include the plurality of mirror blocks 1510, and may be configured to reflect the light L emitted along the optical axis 1110 toward the first surface of the photomask 101′. In FIGS. 8A and 8B, reference numeral 1513 denotes a mirror block in the on state, and reference numeral 1511 denotes a mirror block in the off state. According to embodiments, the DMD 1500 may include the plurality of mirror blocks 1510 configured to be switched between the on state 1513 and the off state 1511. Each of the mirror blocks 1510 may be configured to, in the on state 1513, reflect the light L emitted along the optical axis 1110 toward the first surface of the photomask 101′, and to, in the off state 1511, reflect the light L toward the outside of the photomask 101′.

According to embodiments, the mirror blocks 1510 of the DMD 1500 may be configured to, when at least some of the mirror blocks 1510 are in the on state 1513, reflect the light L emitted along the optical axis 1110 to the entire first surface of the photomask 101′.

According to embodiments, the DMD 1500 may include the plurality of mirror blocks 1510 arranged in the form of an L×M matrix. According to embodiments, the DMD 1500 may include the mirror blocks 1510 arranged in the form of a 1920×1080 matrix, but a matrix form of the mirror blocks 1510 is not limited thereto.

The DMD controller 1600 may be configured to control an on-off state of each of the mirror blocks 1510 of the DMD 1500. The DMD controller 1600 may generate a signal for switching each of the mirror blocks 1510 of the DMD 1500 to the on state 1513 or the off state 1511.

According to embodiments, when the target correction patterns CP detected by the inspector 1800 are the first target correction pattern CP1 (see FIG. 4) and the second target correction pattern CP2 (see FIG. 4), the DMD controller 1600 may specify a first corresponding region 1520, which is a set of mirror blocks that reflect the light L emitted along the optical axis 1110 to the first target correction pattern CP1, and a second corresponding region 1530, which is a set of mirror blocks that reflect the light L emitted along the optical axis 1110 to the second target correction pattern CP2, may generate a signal for switching/maintaining each of the mirror blocks corresponding to the first and second corresponding regions 1520 and 1530 to/in the on state 1513, and may generate a signal for switching/maintaining mirror blocks other than the mirror blocks corresponding to the first and second corresponding regions 1520 and 1530, that is, mirror blocks corresponding to the non-correction region NCR, to/in the off state 1511. Accordingly, operation S410 of preparing the DMD including the plurality of mirror blocks configured to be switched between the on state and the off state, and operation S420 of switching the mirror blocks corresponding to the target correction region to the on state and switching the mirror blocks corresponding to the non-correction region to the off state may be performed.

Operation S430 of providing the light to the DMD and correcting the target correction pattern by using the light reflected from the DMD may be performed as follows.

The light source 1100 may be configured to emit the light L along the optical axis 1110. According to embodiments, the light L emitted along the optical axis 1110 may include a laser beam form.

The light L emitted along the optical axis 1110 may be reflected to the photomask 101′ by the plurality of mirror blocks 1510 of the DMD 1500. Due to operation S410 of preparing the DMD including the plurality of mirror blocks configured to be switched between the on state and the off state, and operation S420 of switching the mirror blocks corresponding to the target correction region to the on state and switching the mirror blocks corresponding to the non-correction region to the off state, each of the mirror blocks 1510 corresponding to the first corresponding region 1520 and the second corresponding region 1530 may be in the on state 1513, and each of the mirror blocks 1510 corresponding to the non-correction region NCR may be in the off state 1511. Accordingly, the light L provided to the DMD 1500 may be reflected by the plurality of mirror blocks 1510 in the on state 1513 and irradiated only to the target correction region CR of the photomask 101′, and the light L may not be irradiated to the non-correction region NCR. As a result, the light L provided to the DMD 1500 may be irradiated to each of the target correction patterns CP of the photomask 101′ by the plurality of mirror blocks 1510 in the on state 1513.

The temperature of an etchant located in a region to which the light L is irradiated, that is, at least one target correction pattern CP, or in the vicinity of the target correction pattern CP may increase due to energy of the light L.

When the temperature of the target correction region CR increases due to the light L in a state in which an etchant is supplied to the photomask 101′, critical dimension correction of at least one target correction pattern CP located in the target correction region CR of the photomask 101′ may be performed.

Referring to the Arrhenius equation below, an increase in temperature of an etchant may increase an etching rate based on a chemical reaction.

$$k = A {e}^{- \frac{E}{R T}}$$

(k: a reaction rate constant, A and E: intrinsic numerical constants according to a reactant, R: a gas constant, T: an absolute temperature)

The reaction rate constant K increases as the temperature T of an etchant increases, and thus, the reaction rate of an etchant irradiated with light may be higher than that of an etchant not irradiated with light. Accordingly, a pattern in contact with the etchant to which the light L is irradiated, that is, the target correction pattern CP, may be etched faster than other regions to which the light L is not irradiated. As a result, the target correction pattern CP may be selectively etched.

According to embodiments, a plurality of target correction patterns CP may be provided. In this case, the DMD 1500 and the DMD controller 1600 may simultaneously irradiate light to each of the plurality of target correction patterns CP. The temperature of an etchant located in a region irradiated with light, that is, the target correction region CR, may increase due to energy of the light. Accordingly, critical dimensions of the plurality of target correction patterns CP may be simultaneously corrected by increasing the etching speed of the plurality of target correction patterns CP in contact with the etchant.

In the case of critical dimension correction of a general photomask pattern, the correction is performed locally. When there are a plurality of target correction patterns, after critical dimension correction of one target correction pattern is completed, processes of moving the irradiation position of the light L according to another target correction pattern and then irradiating the light L thereto are repeatedly performed, which is time-consuming and inefficient.

However, in the photomask processing apparatus and the photomask processing method of the disclosure, the light L may be reflected through the DMD 1500, and through the plurality of mirror blocks 1510 of the DMD 1500 that have an on-off function, the light L may be simultaneously irradiated to the target correction patterns CP that require correction among the patterns PR of the photomask. Accordingly, in the photomask processing apparatus and the photomask processing method of the disclosure, the critical dimension of at least one target correction pattern CP, which requires critical dimension correction, may be simultaneously corrected, and the yield of a photomask may be increased.

In some embodiments, to increase the precision of etching by the light L, the wavelength of the light L may be selected such that the light L is not absorbed by a chemical liquid but is absorbed by the target correction region CR of the photomask 101′ to increase the temperature of the target correction region CR or an etchant adjacent to the target correction region CR. The light L employed in the present embodiment may have a wavelength not absorbed by the etchant. The wavelength range of the light L may be set based on water that occupies a significant portion of the etchant. Considering the wavelength absorption rate of water, the wavelength of the light L may be in the range of about 200 nm to about 700 nm. In some embodiments, the wavelength of the light L may be in the range of about 400 nm to about 600 nm. For example, the light L may be KrF, XeCl, ArF, KrCl, Ar, YAG, or CO₂ light.

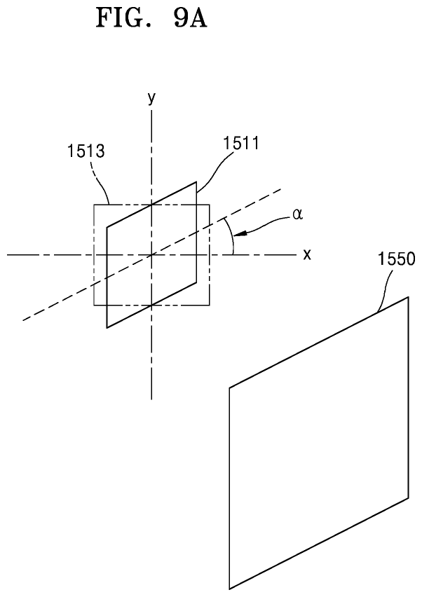

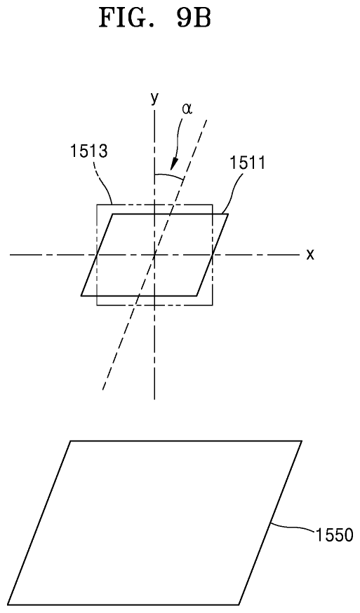

FIGS. 9A and 9B are schematic diagrams of an example of on-off state switching of the mirror block 1510 and a bumper unit 1550 according to an embodiment.

Referring to FIGS. 9A and 9B, the on-off state switching of the mirror block 1510 may be performed through rotation of the mirror block 1510. According to embodiments, an on-off state of the mirror block 1510 may be switched by rotating the mirror block 1510 by an angle α with respect to the Y-axis. According to embodiments, the on-off state of the mirror block 1510 may be switched by rotating the mirror block 1510 by the angle α with respect to the X-axis. When the mirror block 1510 is in the off state 1511, the light L reflected by the mirror block 1510 in the off state 1511 may be reflected to a location other than the photomask 101′.

According to embodiments, the DMD 1500 may further include the bumper unit 1550 configured to absorb the light L reflected to the location other than the photomask 101′ by the mirror block 1510 in the off state 1511. The bumper unit 1550 may be at the location the light L reflected by the mirror block 1510 in the off state 1511 arrives. The bumper unit 1550 may prevent re-reflection or scattering of the light L reflected by the mirror block 1510 in the off state 1511, so that the light L reflected by the mirror block 1510 in the off state 1511 does not affect pattern correction of the photomask 101′.

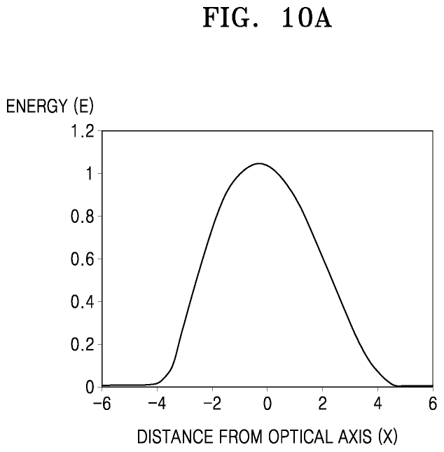

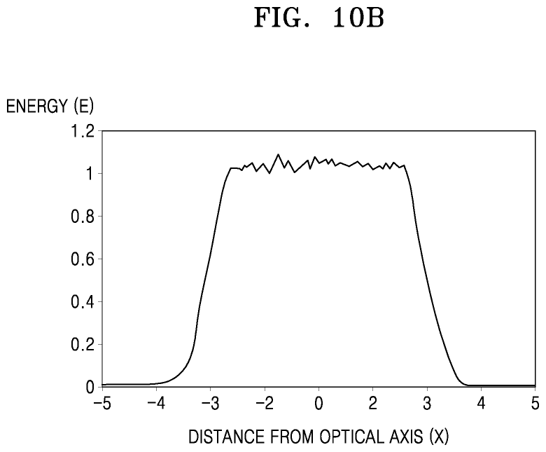

FIGS. 10A and 10B are graphs for explaining a flat-top optical system 1200 according to an embodiment.

Referring to FIGS. 5, 10A, and 10B, the photomask processing apparatus 1000 may include the flat-top optical system 1200. The flat-top optical system 1200 may be configured to convert the light L emitted along the optical axis 1110 into flat-top light having a square uniform energy distribution. As shown in FIG. 10A, general light may have a lower energy value away from the optical axis 1110. However, light having passed through the flat-top optical system 1200 is converted to have a square uniform energy distribution, as shown in FIG. 10B.

As a result, the photomask processing apparatus 1000 including the flat-top optical system 1200 may irradiate light having uniform energy to the target correction region CR, and accordingly, the temperature at which an etchant is raised may be accurately calculated, so that the critical dimension of the target correction pattern CP may be accurately corrected.

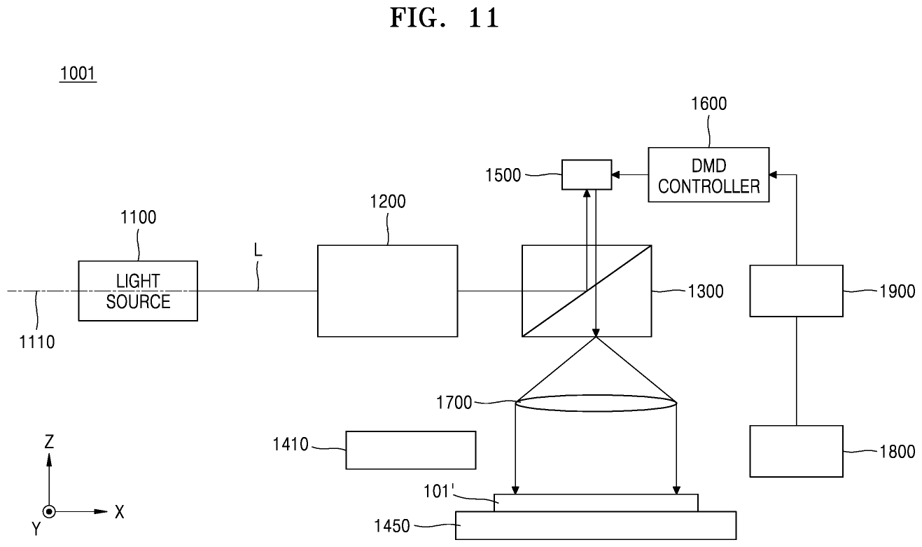

FIG. 11 is a schematic configuration diagram of a photomask processing apparatus 1001 according to an embodiment. Referring to FIG. 11, the photomask processing apparatus 1001 may include the support unit 1450, the inspector 1800, the fluid supply unit 1410, the light source 1100, the light irradiation optical system 1300, the DMD 1500, the DMD controller 1600, and a temperature measuring device 1900.

Hereinafter, redundant descriptions of the photomask processing apparatus 1000 of FIG. 5 and the photomask processing apparatus 1001 of FIG. 11 are omitted, and differences therebetween are mainly described.

The temperature measuring device 1900 may be configured to measure the temperature of an etchant or the temperature of the plurality of patterns PR of the photomask 101′. According to embodiments, the temperature measuring device 1900 may include a thermal imaging camera. According to embodiments, the temperature measuring device 1900 may have pixels corresponding to the number of mirror blocks 1510.

When a plurality of target correction patterns CP are provided, target critical dimensions of the plurality of target correction patterns CP may be different. Accordingly, a target temperature of an etchant located on each of the target correction patterns CP may be different.

The DMD controller 1600 may generate a signal for controlling on-off states of the mirror blocks 1510 of the DMD 1500 based on the temperature of the etchant located on each of the target correction patterns CP, measured by the temperature measuring device 1900.

For example, when a portion of the etchant located on each of the plurality of target correction patterns CP reaches the target temperature, the mirror blocks 1510 that reflect the light L to the etchant may be feedback-controlled to the off state 1511. That is, the mirror blocks 1510 that reflect the light L to the target correction pattern CP for which the target critical dimension has been obtained by critical dimension correction may be feedback-controlled to the off state 1511.

In contrast, the mirror blocks 1510 that reflect the light L to a portion of the etchant located each of the plurality of target correction patterns CP that does not reach the target temperature, that is, the target correction patterns CP that does not reach the target critical dimension by the correction, may be controlled to be maintained in the on state 1513.

As a result, the DMD controller 1600 may feedback-control the on-off states of the mirror blocks 1510 based on the temperature of the etchant measured by the temperature measuring device 1900. Accordingly, even when the target critical dimensions of the plurality of target correction patterns CP are different, the critical dimension of each of the plurality of target correction patterns CP may be accurately corrected.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the disclosure as defined by the following claims.

What is claimed is:

1. A photomask processing apparatus comprising:
a light source configured to emit light along an optical axis;
a photomask comprising a first surface provided with a plurality of patterns;
an inspector configured to detect a target correction region comprising at least one target correction pattern having a dimension greater than a predetermined target range, among the plurality of patterns; and
a digital micromirror device (DMD) comprising a plurality of mirror blocks and configured to switch each of the plurality of mirror blocks between an on state and an off state,
wherein each of the plurality of mirror blocks is configured to, in the on state, reflect the emitted light toward the first surface of the photomask and, in the off state, reflect the emitted light toward outside of the first surface of the photomask, and
the DMD is further configured to switch, to the on state, mirror blocks corresponding to the target correction region of the first surface of the photomask among the plurality of mirror blocks, and switch, to the off state, mirror blocks corresponding to a non-correction region among the plurality of mirror blocks, the non-correction region being a region other than the target correction region on the first surface of the photomask.

2. The photomask processing apparatus of claim 1, wherein the at least one target correction pattern comprises a pattern having a critical dimension greater than a deviation of a target critical dimension of each of the plurality of patterns, among the plurality of patterns.

3. The photomask processing apparatus of claim 1, further comprising a fluid supply unit configured to supply an etchant to the first surface of the photomask.

4. The photomask processing apparatus of claim 1, wherein on-off state switching of each of the plurality of mirror blocks is performed through rotation of each of the plurality of mirror blocks.

5. The photomask processing apparatus of claim 4, further comprising a bumper unit configured to absorb the light reflected by the plurality of mirror blocks in the off state.

6. The photomask processing apparatus of claim 1, further comprising a flat-top optical system configured to convert the light emitted along the optical axis into flat-top light.

7. The photomask processing apparatus of claim 1, further comprising:
a temperature measuring device configured to measure a temperature of the at least one target correction pattern; and
a DMD controller configured to control on-off state switching of the plurality of mirror blocks of the DMD.

8. The photomask processing apparatus of claim 7, wherein the DMD controller is further configured to control, based on the temperature of the at least one target correction pattern measured by the temperature measuring device, on-off states of the plurality of mirror blocks corresponding to the at least one target correction pattern so that the temperature of the at least one target correction pattern reaches a target temperature.

9. The photomask processing apparatus of claim 1, further comprising a light irradiation optical system configured to provide the light emitted along the optical axis to the DMD.

10. The photomask processing apparatus of claim 9, wherein the light irradiation optical system is further configured to provide the light emitted along the optical axis to the DMD in a direction different from the optical axis.

11. The photomask processing apparatus of claim 1, wherein the DMD comprises the plurality of mirror blocks arranged in a form of an L×M matrix.

12. The photomask processing apparatus of claim 1, further comprising a refractive lens configured to adjust magnification of the light reflected from the DMD.

13. A photomask processing method comprising:
preparing a photomask comprising a first surface provided with a plurality of patterns;
determining a target correction region comprising at least one target correction pattern having a dimension greater than a predetermined target range, with respect to the photomask;
supplying an etchant to the first surface of the photomask; and
correcting a dimension of the at least one target correction pattern by irradiating light to the target correction region of the photomask,
wherein the correcting of the dimension of the at least one target correction pattern comprises:
preparing a digital micromirror device (DMD) comprising a plurality of mirror blocks each configured to be switched between an on state and an off state, each of the plurality of mirror blocks being further configured to, in the on state, reflect the light toward the first surface of the photomask and, in the off state, reflect the light toward outside of the first surface of the photomask;
switching, to the on state, mirror blocks corresponding to the target correction region among the plurality of mirror blocks and switching, to the off state, mirror blocks corresponding to a non-correction region among the plurality of mirror blocks, the non-correction region being a region other than the target correction region on the first surface of the photomask; and
providing the light to the DMD and etching the at least one target correction pattern by using the light reflected from the DMD.

14. The photomask processing method of claim 13, wherein the at least one target correction pattern comprises a pattern having a critical dimension greater than a deviation of a target critical dimension of each of the plurality of patterns, among the plurality of patterns.

15. The photomask processing method of claim 13, wherein the preparing of the DMD comprises adjusting magnification of the reflected light to correspond to a size of the photomask.

16. The photomask processing method of claim 13, wherein on-off state of each of the plurality of mirror blocks is performed through rotation of each of the plurality of mirror blocks.

17. The photomask processing method of claim 13, wherein, in the etching of the at least one target correction pattern, the light is provided to the DMD through a light irradiation optical system configured to change a path of the light.

18. The photomask processing method of claim 13, wherein the correcting of the dimension of the at least one target correction pattern further comprises:
measuring a temperature of the at least one target correction pattern; and
feedback-controlling, based on the measured temperature, on-off states of the plurality of mirror blocks corresponding to the at least one target correction pattern so that the temperature of the at least one target correction pattern reaches a target temperature.

19. The photomask processing method of claim 13, wherein the etching of the at least one target correction pattern comprises converting the light into flat-top light.

20. A photomask processing method comprising:
preparing a mask blank comprising a mask substrate, a reflective multi-layer film located on the mask substrate and configured to reflect extreme ultraviolet (EUV) light, and an absorbing layer located on the reflective multi-layer film;
etching the absorbing layer to provide a photomask comprising a first surface provided with a plurality of patterns;
detecting a target correction region comprising at least one target correction pattern among the plurality of patterns, the at least one target correction pattern being a pattern having a greater width than a deviation of a critical dimension of each of the plurality of patterns;
supplying an etchant to the first surface of the photomask; and
correcting, in a state in which the etchant is supplied, a critical dimension of the at least one target correction pattern by irradiating light to the target correction region,
wherein the correcting of the critical dimension of the at least one target correction pattern comprises:
preparing a digital micromirror device (DMD) comprising a plurality of mirror blocks each configured to be switched between an on state and an off state, each of the plurality of mirror blocks being further configured to, in the on state, reflect the light toward the first surface of the photomask and, in the off state, reflect the light toward outside of the first surface of the photomask;
switching, to the on state, mirror blocks corresponding to the target correction region among the plurality of mirror blocks and switching, to the off state, mirror blocks corresponding to a non-correction region among the plurality of mirror blocks, the non-correction region being a region other than the target correction region on the first surface of the photomask; and
providing the light to the DMD and etching the at least one target correction pattern by using the light reflected from the DMD.
